(19) United States
(12) Patent Application Publication
(10) Pub. No.: US 2003/0234037 A1
(43) Pub. Date: Dec. 25, 2003

(54) Thermoelectric conversion unit and thermoelectric module

(75) Inventor: Koichi Tanaka, Kokubu (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 10/422,636

(22) Filed: Apr. 24, 2003

(30) Foreign Application Priority Data
Apr. 24, 2002 (JP) 2002-123056

(51) Int. Cl. H01L 35/30; H01L 35/12

(52) U.S. Cl. 136/205; 136/240; 136/238; 136/236.1

(57) ABSTRACT

A thermoelectric conversion unit comprising a thermoelectric conversion device 1 having a cleavage plane 2 and electrodes 3 formed on a pair of opposing surfaces of the thermoelectric conversion device 1, the angle subtended by the electrode-forming surfaces 4 of the thermoelectric conversion device 1 and by the cleavage plane 2 being not smaller than 45 degrees, the surface roughness Ra on the electrode-forming surfaces 4 being from 0.1 to 5 μm, and the electrodes 3 having a thickness larger than a maximum surface roughness Rmax of the electrode-forming surfaces 4. The thermoelectric conversion unit features a high adhesion strength between the thermoelectric conversion device 1 and the electrodes 3, and high reliability.

### BACKGROUND OF THE INVENTION

1. Field of the Invention.

The present invention relates to a thermoelectric conversion unit preferably used for cooling the heat-generating members such as semiconductors and to a thermoelectric module.

2. Description of the Related Art.

A thermoelectric conversion device which utilizes Peltier effect generates heat at one end thereof when an electric current is supplied thereto and absorbs heat at the other end thereof, and has, hence, been used for cooling. In particular, a thermoelectric module obtained by electrically connecting in series, on supporting boards, a plurality of thermoelectric conversion units comprising the above thermoelectric conversion devices with electrodes, has been expected to be used in a wide range of applications such as devices for controlling the temperature of a laser diode, small and simply constructed cooling devices, refrigerators, constant temperature baths, optical detector devices, electronic cooling equipment such as apparatus for producing semiconductors, devices for adjusting the temperature of a laser diode, etc.

The thermoelectric module has a structure as shown in, for example, FIG. 3. That is, wiring conductors 23a and 23b are formed on the surfaces of supporting boards 22a and 22b, and a plurality of thermoelectric conversion devices 25 comprising P-type thermoelectric conversion devices 25a and N-type thermoelectric conversion devices 25b are held between the supporting boards 22a and 22b. These thermoelectric conversion devices 25 are electrically connected in series through wiring conductors 23a and 23b, and are, further, connected to external connection terminals 27. External wirings 29 are connected to the external connection terminals 27 by soldering 28, and electric power can be supplied thereto from an external unit.

Copper is used as the wiring conductors 23a and 23b. Electrodes are formed by plating nickel or the like metal on the surfaces of the thermoelectric conversion devices 25 that connect to the wiring conductors 23a and 23b in order to strengthen the junction of solder to the thermoelectric conversion devices 25, to improve wettability of solder to the thermoelectric conversion devices 25 and to prevent the solder components from diffusing. That is, a thermoelectric conversion unit is constituted by the thermoelectric conversion device 25 and the electrodes (not shown in FIG. 3).

In a thermoelectric module for cooling used nearly at room temperature, A₂B₃ type crystals (A is Bi and/or Sb, B is Te and/or Se) are generally used as the thermoelectric conversion devices 25. As the P-type thermoelectric conversion devices 25a, for example, there is widely used a solid solution of Bi₂Te₃ and Sb₂Te₃ (antimony telluride) and as the N-type thermoelectric conversion devices 25b, for example, there is widely used a solid solution of Bi₂Te₃ and Bi₂Se₃ (bismuth selenide). These A₂B₃ type crystals exhibit excellent thermoelectric characteristics and are best suited as thermoelectric conversion devices 25 used for a thermoelectric module accompanied, however, by a defect in that it is difficult to obtain a large and complete single crystal.

International Patent Application No. 2000-507398 discloses an ingot plate of a thermoelectric material comprising A₂B₃ crystals, exhibiting excellent thermoelectric characteristics and offering a practicable nature. The ingot plate is polycrystalline having a plurality of cleavage directions which are aligned at 26.4° or at smaller angles, and can be produced inexpensively without impairing its excellent thermoelectric characteristics.

The above thermoelectric material (ingot plate) has cleavage directions which are aligned within a particular range exhibiting excellent thermoelectric characteristics. When electrodes are formed thereon by plating or the like method, however, the electrodes tend to be easily peeled off. Therefore, the thermoelectric conversion unit having electrodes formed thereon easily develops defects and lacks reliability.

### SUMMARY OF THE INVENTION

It is therefore an object of the present invention to provide a thermoelectric conversion unit featuring a high adhesion strength between the thermoelectric conversion device and the electrodes, effectively preventing the electrodes from peeling, and featuring a high reliability, as well as a thermoelectric module using the above units.

The present inventors have discovered a novel fact that when electrodes are formed on the surfaces of the thermoelectric conversion device having a cleavage plane, the adhesion strength between the electrodes and the thermoelectric conversion device varies greatly depending upon the angle subtended by the electrode-forming surfaces of the device and the cleavage plane, and further depending upon a relationship between the surface roughness of the electrode-forming surfaces and the thickness of the electrodes, and have thus arrived at the present invention.

According to the present invention, there is provided a thermoelectric conversion unit comprising a thermoelectric conversion device having a cleavage plane and electrodes formed on a pair of opposing surfaces of the thermoelectric conversion device, an angle subtended by the electrode-forming surfaces of the thermoelectric conversion device and by the cleavage plane being not smaller than 45 degrees.

In the present invention, it is most desired that the electrode-forming surfaces of the thermoelectric conversion devices have an average surface roughness Ra (JIS B 0601) of from 0.1 to 5 μm and that the electrodes have a thickness larger than a maximum surface roughness Rmax (JIS B 0601) of the electrode-forming surfaces.

Namely, in the present invention, the angle subtended by the cleavage plane and by the electrode-forming surfaces is adjusted to lie within a predetermined range and, besides, the surface roughness of the electrode-forming surfaces and the thickness of the electrodes are controlled to enhance the adhesion strength between the thermoelectric device and the electrodes and to effectively avoid a drop in the performance of the thermoelectric conversion unit and a decrease in the life.

In the thermoelectric conversion unit of the present invention, further, it is desired that the thermoelectric conversion device (i.e., the one of either the N-type or the P-type) comprises crystals containing at least two kinds of Bi, Sb, Te and Se. This makes it possible to obtain favorable cooling performance near the normal temperature.

Further, the angle subtended by the electrode-forming surfaces and the cleavage plane is selected to be 90±5 degrees to maximize the adhesion strength between the thermoelectric device and the electrodes.

It is desired that the electrodes contain at least one kind of Ni, Au, Sn, Pt and Co to heighten the wettability of solder and to prevent the solder components from diffusing. In order to further enhance the wettability of solder and to more effectively prevent the diffusion of solder components, it is desired that the electrodes have a thickness of from 1 to 30 μm.

In the thermoelectric conversion unit of the invention described above, the adhesion strength between the thermoelectric conversion device and the electrodes is not smaller than 10 MPa effectively preventing a drop in the performance caused by the peeling electrodes and a decrease in the life.

The above-mentioned thermoelectric conversion units of the present invention can be used as a thermoelectric module being arranged in a plural number on predetermined supporting boards. Namely, the thermoelectric module comprises supporting boards and a plurality of thermoelectric conversion units arranged on the supporting boards, the plurality of thermoelectric conversion units being electrically connected together through wiring conductors and further being electrically connected to external connection terminals through wiring conductors. The thermoelectric module using the thermoelectric conversion units of the invention features excellently stable performance and long life.

### BRIEF DESCRIPTION OF THE DRAWINGS

FIG. 1 is a sectional view schematically illustrating a thermoelectric conversion unit according to the present invention;

FIG. 2 is a sectional view schematically illustrating the thermoelectric conversion unit according to a preferred embodiment of the present invention;

FIG. 3 is a perspective view schematically illustrating a thermoelectric module using the thermoelectric conversion units;

FIG. 4 is a sectional view schematically illustrating a conventional thermoelectric conversion unit; and

FIGS. 5a and 5b are views schematically illustrating the state of an electrode-forming surface of a thermoelectric conversion device in the thermoelectric conversion unit, wherein FIG. 5a is a view of when the angle θ subtended by the electrode-forming surface and the cleavage plane is about 45 degrees and FIG. 5b is a view of when the angle θ is about 90 degrees.

### DETAILED DESCRIPTION OF THE INVENTION

(Thermoelectric Conversion Unit)

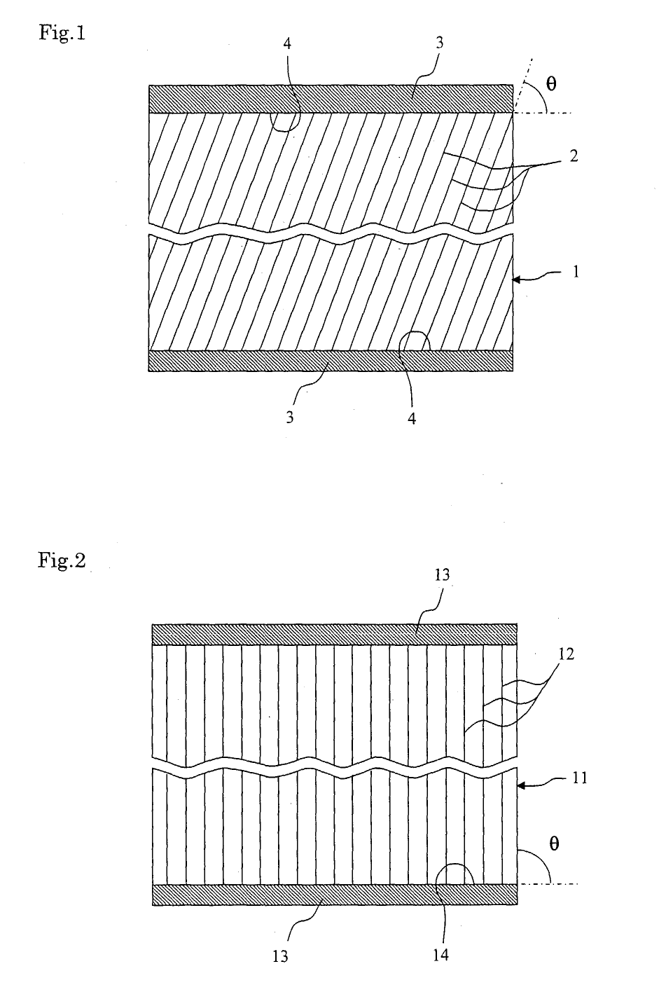

Referring to FIG. 1 schematically illustrating the structure of a thermoelectric conversion unit of the present invention, the thermoelectric conversion unit comprises a P-type or N-type thermoelectric conversion device 1, and a pair of electrodes 3 and 3. The electrodes 3 and 3 are formed on a pair of opposing surfaces (electrode-forming surfaces) 4 and 4 of the thermoelectric conversion device 1.

In the present invention, it is important that the thermoelectric conversion device 1 has a cleavage plane 2 and that the angle θ subtended by the cleavage plane 2 and the electrode-forming surfaces 4 is not smaller than 45 degrees. When the angle θ is smaller than 45 degrees, the electrodes 3 become nearly in parallel with the direction of cleavage of the electrode-forming surfaces 4, whereby peeling occurs along the cleavage plane 2 of the thermoelectric conversion device permitting the electrodes 3 to peel off and cracks to occur. In a conventional thermoelectric conversion unit as shown in, for example, FIG. 4, the angle θ subtended by the cleavage plane 32 of the thermoelectric conversion device and the electrode-forming surfaces 34 is smaller than 45 degrees, the cleavage plane 32 is nearly in parallel with the electrode-forming surfaces 34, and peeling occurs easily along the cleavage plane 32. Once the peeling occurs, the electrodes 33 on the electrode-forming surfaces 34 are also partly peeled.

In order to more effectively prevent the electrodes 3 from peeling in the present invention, therefore, it is desired that the electrode-forming surfaces 4 and the cleavage plane 2 are far from being in parallel with each other. Concretely speaking, it is desired that the angle θ is not smaller than 60 degrees, preferably, not smaller than 70 degrees and, most preferably, not smaller than 80 degrees and, most preferably, nearly at right angles (90±5 degrees). FIG. 2 illustrates a case of when the angle θ is nearly 90 degrees.

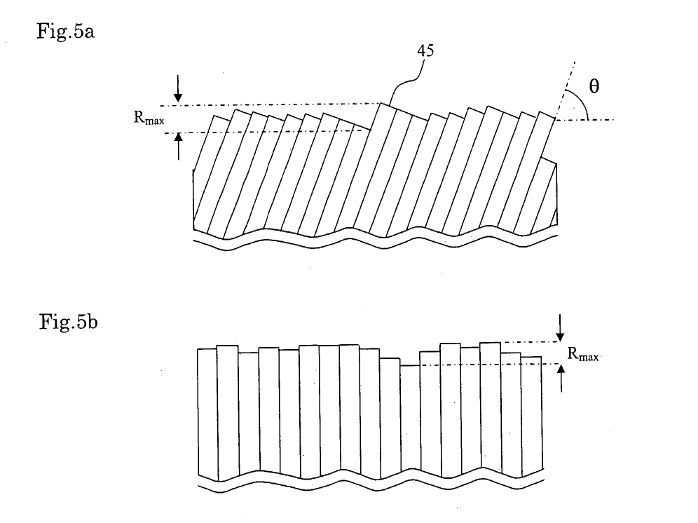

Reference should be made to FIGS. 5a and 5b illustrating the surface states of the thermoelectric conversion device (states of the electrode-forming surfaces 4). FIG. 5a illustrates a case of when the angle θ is about 45 degrees and FIG. 5b illustrates a case of when the angle θ is nearly 90 degrees. In either case, the electrode-forming surfaces 4 are rugged as designated at 45. The surfaces become very rugged and the surface roughness becomes great particularly when the electrode-forming surfaces are formed by cutting the cleavage plane 2. The electrodes 3 easily peel off when they are formed on the surfaces having such a large ruggedness. Therefore, reliability was low when the conventional ingot plate was used.

According to the present invention, the average surface roughness Ra (JIS B 0601) on the electrode-forming surfaces is controlled to lie in a range of from 0.1 to 5 μm, preferably, from 0.3 to 3 μm and, most preferably, from 0.5 to 2 μm (i.e., ruggedness 45 is decreased) to suppress mechanical peeling due to cleavage, to improve anchoring effect, and to further increase the adhesion strength between the electrodes 3 and the thermoelectric conversion device 1. This is further advantageous even from the standpoint of maintaining smoothness of the electrodes 3 and preventing a drop in the wettability of the solder.

It is further desired that the average surface roughness Ra is selected to lie within the above range and that the thickness of the electrodes 3 is selected to be greater than a maximum surface roughness Rmax (FIGS. 5a and 5b) of the electrode-forming surfaces 4. When the thickness of the electrodes 3 is not larger than the maximum surface roughness Rmax, cleavage occurs from the electrode-forming surfaces 3; i.e., cleavage occurs through the after-treatment such as dicing after the electrodes have been formed, and the edges of the electrodes 3 are cut away due to the cleavage. Upon selecting the thickness of the electrodes 3 to be not smaller than the maximum surface roughness Rmax, the electrode-forming surfaces are protected, and the electrodes 3 are effectively prevented from peeling at their ends, that is caused by cleavage.

It is desired that the above thermoelectric conversion device 1 is constituted by crystals containing at least two kinds of Bi, Sb, Te and Se. The thermoelectric conversion device 1 having a particularly high figure of merit is, desirably, an A₂B₃ type intermetallic compound or a solid solution of such an intermetallic compound, such as A₂B₃ type semiconductor crystals of which the A-site is Bi and/or Sb and of which the B-site is Te and/or Se. The thermoelectric conversion device 1 having a composition ratio B/A of 1.4 to 1.6 exhibits a high figure of merit at room temperature, and can be most desirably used in the invention as the thermoelectric device 1.

Concrete examples of the intermetallic compound include Bi₂Te₃, Sb₂Te₃ and Bi₂Se₃. As the solid solution of the intermetallic compound, further, there can be exemplified Bi₂Te₃₋ₓSeₓ (x=0.05 to 0.25) which is a solid solution of Bi₂Te₃ and Bi₂Se₃, and BiₓSb₂₋ₓTe₃ (x=0.1 to 0.6) which is a solid solution of Bi₂Te₃ and Sb₂Te₃.

In order to efficiently transform the intermetallic compound or the solid solution into a semiconductor, further, an impurity may be added as a dopant. In order to obtain, for example, an N-type thermoelectric conversion device, the starting powder of an intermetallic compound is blended with at least one kind of a compound containing halogen elements such as I, Cl or Br (e.g., AgI powder, CuBr powder, SbI₃ powder, SbCl₃ powder, SbBr₃ powder, HgBr₂ powder, etc.) to adjust the carrier concentration in the intermetallic compound semiconductor. As a result, it is made possible to increase a figure of merit. It is desired that the halogen compound is contained in the starting powder at a ratio of from 0.01 to 5% by weight and, particularly, from 0.05 to 4% by weight from the standpoint of efficiently transforming the intermetallic compound into a semiconductor. In order to obtain a P-type thermoelectric conversion device, further, Te may be added to the starting powder to adjust the carrier concentration. This makes it possible to enhance the figure of merit like in the case of the N-type thermoelectric conversion device and to obtain a good cooling performance near the normal temperature.

It is further desired that the above electrodes 3 contain at least one of Ni, Au, Sn, Pt and Co. It is particularly desired that the electrodes 3 are formed by the Ni layer and the Au layer (Au layer is on the front surface side). Namely, in joining the wiring conductor to the electrodes 3 by using a solder, the diffusion of solder components is suppressed by the Ni layer and the wettability to the solder is improved by the Au layer. Further, the Ni layer may be suitably formed by an alloy such as Ni—B or Ni—P. The Ni layer can be further formed by laminating the above alloy layers in two layers thereby to enhance the adhesion to the thermoelectric conversion device 1 or to improve performance for preventing the diffusion of solder components.

The thermoelectric conversion unit of the present invention comprising the above-mentioned thermoelectric conversion device 1 and the electrodes 3, has an adhesion strength between the electrodes 3 and the thermoelectric conversion device 1 of, usually, not smaller than 10 MPa, preferably, not smaller than 12 MPa and, most preferably, not smaller than 14 MPa, effectively suppressing a drop in the performance and a decrease in the life caused by the peeling electrodes 3. The adhesion strength is evaluated by a tensile strength of electrodes 3, which is measured by soldering a lead wire to the electrode 3 of the thermoelectric conversion unit cut into a square of a size of 1 mm and by measuring its tensile strength.

(Production of a Thermoelectric Conversion Unit)

The thermoelectric conversion unit of the present invention is produced in a manner as described below.

As the starting powders for the thermoelectric conversion material, first, there are prepared various powders (Te powder, Bi powder, Sb powder, Se powder) having purities of not smaller than 99.9% and average particle diameters of from 1 to 100 μm. These powders are mixed together in predetermined amounts and are melted. It is desired that the powders are melted in a sealed container filled with an inert gas to prevent a variation in the composition caused by oxidation and volatilization. The powders are melted with stirring so as to be transformed into an alloy thereof to a sufficient degree, followed by cooling to obtain an ingot for a thermoelectric conversion material.

The above ingot is coarsely pulverized, melted again in a sealed container filled with an inert gas, and is gradually cooled and solidified from one end thereof thereby to obtain an N-type or P-type thermoelectric conversion device of which the crystals are oriented in one direction. In order to efficiently transform the intermetallic compound into a semiconductor, the above-mentioned halogen compound is added as a dopant to the powder obtained by coarsely pulverizing the ingot or to the powder of the above starting mixture to obtain a thermoelectric conversion device comprising the above N-type semiconductor crystals having an improved figure of merit. In order to adjust the carrier concentration in the P-type semiconductor crystals, further, Te is added to the powder obtained by coarsely pulverizing the ingot or to the powder of the starting mixture to obtain a P-type thermoelectric conversion device having an improved figure of merit. In conducting the cooling and solidification, further, seed crystals are installed at a solidification starting end to obtain a thermoelectric conversion device which is oriented in one direction more favorably.

The thus obtained thermoelectric conversion device is, as desired, reduced by the heat treatment in a hydrogen stream to remove oxygen introduced by the oxidation.

The obtained thermoelectric conversion device is sliced maintaining a predetermined thickness at an angle of not smaller than 45 degrees with respect to the cleavage plane 2 to form a surface (inclusive of the electrode-forming surface 4) having a predetermined angle θ with respect to the cleavage plane 2. The slicing can be effected by known means such as wire saw or wheel saw. Of the surfaces formed by the slicing, further, a portion corresponding to at least the electrode-forming surface 4 is polished such that the average surface roughness Ra lies within the above predetermined range (0.1 to 5 μm). The polishing is conducted in a customary manner.

The electrodes 3 of a thin Ni film and the like are formed on the electrode-forming surfaces 4 of the thus obtained thermoelectric conversion device by the electroplating method such as electric field plating or non-electric field plating, or the gaseous phase method such as PVD method or CVD method. It is particularly desired to form the electrodes 3 by the electroplating method which is capable of forming a thin film that is highly intimately adhered using a simple facility and at a low cost. In order to improve wettability to the solder, further, the Au layer may be further laminated on the thin Ni layer. It is further desired that the electrodes 3 have a thickness larger than the maximum surface roughness Rmax on the electrode-forming surfaces 4.

Upon dicing the thus obtained thermoelectric conversion device having electrodes 3 into a desired size, there is obtained a thermoelectric conversion unit of the invention.

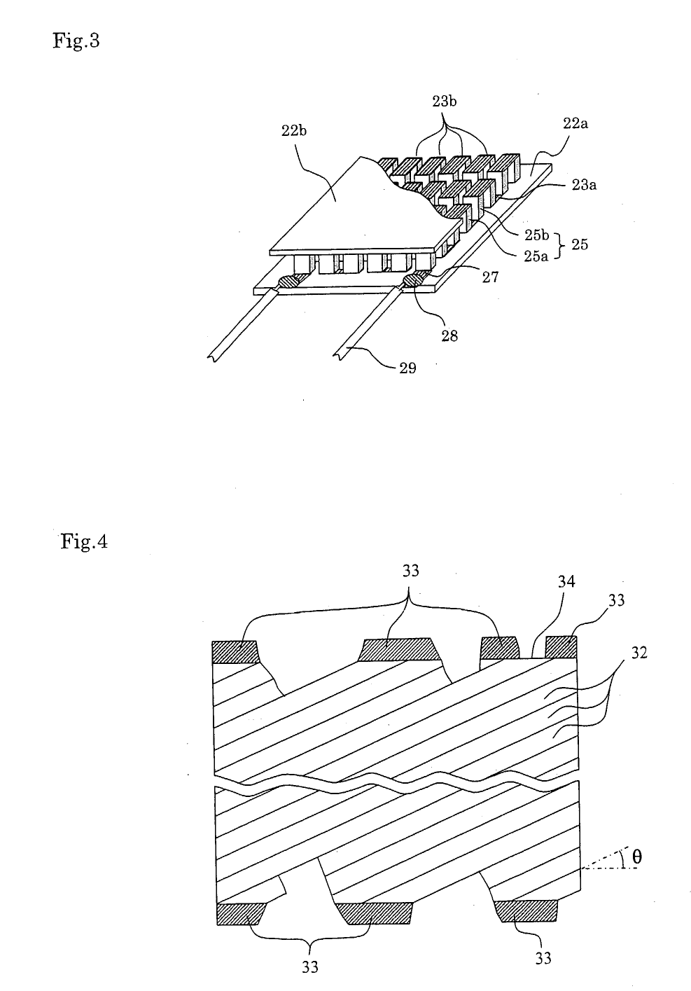

Referring to FIG. 3, a plurality of the thus produced thermoelectric conversion units of the invention are held between a pair of supporting boards 22a and 22b so as to be used as a thermoelectric module. That is, in this thermoelectric module, the P-type thermoelectric conversion devices (25a) and the N-type thermoelectric conversion devices (25b) are alternately arranged, and are electrically connected in series through the wiring conductors 23a and 23b. The wiring conductors 23a and 23b are further connected to the external connection terminals 27. Upon supplying operation electric power from an external unit, the thermoelectric module operates.

As described above, the thermoelectric conversion units of the invention are useful for the fabrication of a thermoelectric module that can be favorably used for controlling the temperature. The thermoelectric module equipped with the thermoelectric conversion units features a long life and stable characteristics.

### EXAMPLES

Excellent effects of the invention will now be described by way of the following experimental examples.

(Experiment 1)

Powders of bismuth, tellurium and selenium having purities of not lower than 99.99% were weighed and mixed together such that Bi₂Te_{2.85}Se_{0.15} as N-type semiconductor was obtained. The mixed powder (starting powder) was contained in a Pyrex glass tube which was maintained vacuum, and melted and stirred in a rocking furnace, followed by cooling to obtain an ingot as a thermoelectric semiconductor material.

The ingot was coarsely pulverized by using a stamp mill. To the coarsely pulverized powder were added SbI₃ in an amount of 0.1% by weight and HgBr₂ in an amount of 0.3% by weight. The mixture was contained again in the Pyrex glass tube that was maintained vacuum, melted and stirred, and was gradually cooled so as to be solidified from one end of the glass tube.

Further, the powders were weighted and mixed together such that Bi_{0.4}Sb_{1.6}Te₃ as P-type semiconductor was obtained.

After cooled, the N-type or P-type semiconductor crystals were taken out from the glass tube, and were so sliced that the angles θ subtended by the cleavage plane and the electrode-forming electrodes were as shown in Table 1. The electrode-forming surfaces of the thus obtained thermoelectric conversion devices were polished to adjust the average surface roughness Ra to be as shown in Table 1 which includes the average surface roughness Ra as well as maximum surface roughness Rmax. The average surface roughness Ra and the maximum surface roughness Rmax were measured in compliance with JIS B 0601 by using a touch-type surface roughness meter.

Next, electrodes (first electrodes) of materials and thicknesses shown in Table 1 were formed on the electrode-forming surfaces by the non-electrolytic plating method and, then, electrodes (second electrodes) comprising Au were formed thereon maintaining a thickness of 0.5 μm. Table 1 shows materials and thicknesses of the first electrodes. The thicknesses of the electrodes were measured along their cross section by using a scanning electron microscope (SEM).

The thus formed thermoelectric conversion devices provided with the electrodes were diced into squares of 1 mm to fabricate thermoelectric conversion units (samples Nos. 1 to 28) for fabricating the thermoelectric module.

Lead wires were soldered to the electrodes of the obtained thermoelectric conversion units and were pulled to peel the electrodes off thereby to measure the force required for the peeling and the adhesion strength based on the peeled areas. Further, the appearance was inspected by using an optical microscope to examine whether the electrodes were peeled off. The results were as shown in Table 1.

TABLE 1

| | | | | | Electrode- | | Adhesion | |
|---|---|---|---|---|---|---|---|---|
| | | | Electrode | | forming surface | | strength | |
| Sample No. | Type | Angle θ (°) | Material | Thickness (μm) | Rmax (μm) | Ra (μm) | MPa | Appearance |
| *1 | N | 0 | Ni | 10 | 3 | 1 | 6 | X |
| *2 | N | 30 | Ni | 10 | 3 | 1 | 8 | X |
| 3 | N | 50 | Ni | 10 | 3 | 1 | 10 | ◯ |
| 4 | N | 70 | Ni | 10 | 3 | 1 | 11 | ◯ |
| 5 | N | 90 | Ni | 3 | 3 | 1 | 12 | ◯ |
| 6 | N | 90 | Ni | 10 | 3 | 1 | 12 | ◯ |
| 7 | N | 90 | Ni | 20 | 3 | 1 | 12 | ◯ |
| 8 | N | 90 | Ni | 10 | 2 | 1 | 11 | ◯ |
| 9 | N | 90 | Ni | 10 | 5 | 1 | 13 | ◯ |
| 10 | N | 90 | Ni | 10 | 7 | 1 | 12 | ◯ |
| 11 | N | 90 | Ni | 10 | 5 | 0.5 | 11 | ◯ |
| 12 | N | 90 | Ni | 10 | 5 | 2 | 13 | ◯ |
| 13 | N | 90 | Ni | 10 | 5 | 4 | 12 | ◯ |
| *14 | N | 90 | Ni | 10 | 15 | 7 | 6 | X |
| *15 | N | 90 | Ni | 10 | 15 | 1 | 4 | X |
| *16 | P | 0 | Ni | 10 | 3 | 1 | 7 | X |
| *17 | P | 30 | Ni | 10 | 3 | 1 | 9 | X |
| 18 | P | 50 | Ni | 10 | 3 | 1 | 11 | ◯ |
| 19 | P | 70 | Ni | 10 | 3 | 1 | 11 | ◯ |
| 20 | P | 90 | Ni | 3 | 3 | 1 | 12 | ◯ |
| 21 | P | 90 | Ni | 10 | 3 | 1 | 12 | ◯ |
| 22 | P | 90 | Ni | 25 | 3 | 1 | 12 | ◯ |
| 23 | P | 90 | Ni | 10 | 5 | 0.5 | 11 | ◯ |
| 24 | P | 90 | Ni | 10 | 5 | 2 | 13 | ◯ |
| 25 | P | 90 | Ni | 10 | 5 | 4 | 13 | ◯ |
| 26 | P | 90 | Sn | 10 | 3 | 1 | 13 | ◯ |
| 27 | P | 90 | Pt | 10 | 3 | 1 | 12 | ◯ |
| 28 | P | 90 | Co | 10 | 3 | 1 | 14 | ◯ |

Samples marked with * lie outside the scope of the invention.
In the appearance, ◯ represent that there was no peeling and X represents that peeling took place.

In the samples (Nos. 3 to 13 and 18 to 28) having an average surface roughness Ra on the electrode-forming surfaces of 0.1 to 5 μm, electrode thicknesses of not smaller than the maximum surface roughness Rmax in the electrode-forming surfaces, and angles θ subtended by the cleavage plane and the electrode-forming surfaces of not smaller than 45 degrees, the electrode adhesion strengths were not smaller than 10 MPa and there was observed no electrode that was peeling.

In the samples Nos. 1, 2, 16 and 17 having angles θ of not larger than 45 degrees, the electrode adhesion strengths were not larger than 10 MPa and there were observed peeling electrodes.

In the samples Nos. 14 and 15 having electrode thicknesses of not larger than the maximum surface roughness Rmax in the electrode-forming surfaces, the electrode adhesion strengths were not larger than 6 MPa and there were observed peeling electrodes.

(Experiment 2)

Thermoelectric modules shown in FIG. 3 were fabricated each by using 23 thermoelectric conversion units of samples Nos. 6 and 21 obtained in Experiment 1. The fabricated modules exhibited performance ΔTmax=72° C.

For comparison, thermoelectric modules shown in FIG. 3 were also fabricated each by using 23 thermoelectric conversion units of samples Nos. 1 and 16.

A cycle testing was conducted 1000 times, each time, by applying a voltage to the thermoelectric module such as the temperature differential was 72° C. between the two pieces of supporting boards, discontinuing the application of voltage for one minute and applying the voltage again.

The thermoelectric modules of the present invention worked normally even after the cycle testing has been finished, but the thermoelectric modules for comparison permitted electrodes to be peeled, could no longer continue the cooling operation after 825 times of the cycle testing indicating a short life.

1. A thermoelectric conversion unit comprising a thermoelectric conversion device having a cleavage plane and electrodes formed on a pair of opposing surfaces of the thermoelectric conversion device, an angle subtended by the electrode-forming surfaces of the thermoelectric conversion device and by the cleavage plane being not smaller than 45 degrees.

2. A thermoelectric conversion unit according to claim 1, wherein an average surface roughness Ra on the electrode-forming surfaces of said thermoelectric conversion device is from 0.1 to 5 μm and the electrodes have a thickness larger than a maximum surface roughness Rmax of said electrode-forming surfaces.

3. A thermoelectric conversion unit according to claim 1, wherein said thermoelectric conversion device comprises crystals containing at least two kinds of Bi, Sb, Te and Se.

4. A thermoelectric conversion unit according to claim 1, wherein the angle subtended by said electrode-forming surfaces and by said cleavage plane is 90±5 degrees.

5. A thermoelectric conversion unit according to claim 1, wherein said electrodes contain at least one kind of Ni, Au, Sn, Pt and Co.

6. A thermoelectric conversion unit according to claim 1, wherein the adhesion strength between said electrodes and the thermoelectric conversion device is not smaller than 10 MPa.

7. A thermoelectric conversion unit according to claim 2, wherein said electrodes have a thickness of from 1 to 30 μm.

8. A thermoelectric module comprising supporting boards and a plurality of thermoelectric conversion units of claim 1 arranged on said supporting boards, said plurality of thermoelectric conversion units being electrically connected together through wiring conductors and further being electrically connected to external connection terminals through wiring conductors.
